(19) United States
(12) Patent Application Publication
(10) Pub. No.: US 2013/0241552 A1
(43) Pub. Date: Sep. 19, 2013

(54) MAGNETIC RESONANCE IMAGING APPARATUS AND CONTRAST-ENHANCED IMAGE ACQUISITION METHOD

(71) Applicant: Kosuke Hirai, Tokyo (JP)

(72) Inventor: Kosuke Hirai, Tokyo (JP)

(73) Assignee: HITACHI MEDICAL CORPORATION, Tokyo (JP)

(21) Appl. No.: 13/989,203

(22) PCT Filed: Nov. 30, 2011
(86) PCT No.: PCT/JP2011/077598

§ 371 Date: May 23, 2013

(30) Foreign Application Priority Data
Dec. 7, 2010 (JP) 2010-272250

(51) Int. Cl. G01R 33/56

(52) U.S. Cl. CPC G01R 33/56
USPC 324/309; 324/318

(57) ABSTRACT

Disclosed are an MRI apparatus and an image contrast enhancement method capable of acquiring an image with enhanced contrast between different tissues while reducing an imaging time even if a SPEC-IR pulse is used as an RF pre-pulse. An echo signal is measured from an object, which includes a first tissue having a first resonance frequency and a second tissue having a second resonance frequency, using a pulse sequence having a RF pre-pulse unit which is provided with an RF pre-pulse having the first resonance frequency for negatively exciting longitudinal magnetization of the first tissue and a measurement sequence unit which measures an echo signal before the longitudinal magnetization excited by the RF pre-pulse is recovered to equal to or greater than zero. A contrast enhancement process for enhancing either tissue relative to the other tissue is performed on an image of the object reconstructed using the echo signal on the basis of phase information of the image to acquire a contrast-enhanced image.

### TECHNICAL FIELD

The present invention relates to a technology which acquires an image with enhanced contrast between a desired tissue and the other tissue when performing tomography (hereinafter, referred to as “MRI”) using a nuclear magnetic resonance (hereinafter, referred to as “NMR”) phenomenon.

### BACKGROUND ART

An MRI apparatus which performs tomography using an NMR phenomenon is an apparatus which measures NMR signals to be generated by nuclear spins forming an object, in particular, a tissue of a human body and images the form or function of a head, an abdomen, four limbs, or the like in a two-dimensional manner or a three-dimensional manner. In the tomography, the NMR signals are given with different kinds of phase encoding by a gradient magnetic field, frequency encoded, and measured as time-series data. The measured NMR signals are subjected to two-dimensional or three-dimensional Fourier transform and reconstructed as images.

As one of the tomography methods which acquire an image with enhanced contrast between different tissues using the MRI apparatus, a method which selectively controls magnetization of a desired tissue on the basis of a difference in the position, T1/T2, or chemical shift between different tissues using a preceding pulse (RF pre-pulse) has been used (for example, PTL 1). In particular, as one of the RF pre-pulses which selectively suppress magnetization of a desired tissue on the basis of a difference in chemical shaft, a SPEC-IR (SPECtrally selected Inversion Recovery) pulse has been known (for example, NPL 1). According to the method using the SPEC-IR pulse, the longitudinal magnetization of a desired tissue is flipped (excited) by 180° using a SPEC-IR pulse having the resonance frequency of the desired tissue, and an echo signal is measured when the longitudinal magnetization flipped by 180° is recovered to null by T1 relaxation. Accordingly, an echo signal from the desired tissue is suppressed, and an image with enhanced contrast between the desired tissue and the other tissue is obtained.

### CITATION LIST

### Patent Literature

PTL 1: JP-A-2009-10113

### Non Patent Literature

NPL 1: Lauenstein T C et al; Evaluation of optimized inversion-recovery fat-suppression techniques for T2-weighted abdominal MR Imaging: J Magn Reson Imaging 2008:27:1448-1454

### SUMMARY OF INVENTION

### Technical Problem

However, since the longitudinal magnetization of the desired tissue is null using the SPEC-IR pulse as the RF pre-pulse before the measurement of the echo signal, there is a problem in that contrast enhancement is not sufficient in the image which is acquired using the SPEC-IR pulse.

Accordingly, the invention has been accomplished in consideration of the above-described problem, and an object of the invention is to provide an MRI apparatus and a contrast-enhanced image acquisition method capable of acquiring an image with enhanced contrast between different tissues even if a SPEC-IR pulse is used as an RF pre-pulse.

### Solution to Problem

In order to attain the above-described object, according to the invention, an echo signal is measured from an object, which includes a first tissue having a first resonance frequency and a second tissue having a second resonance frequency, using a pulse sequence having a RF pre-pulse unit which is provided with an RF pre-pulse having the first resonance frequency for negatively exciting longitudinal magnetization of the first tissue and a measurement sequence unit which measures the echo signal before the longitudinal magnetization excited by the RF pre-pulse is recovered to equal to or greater than zero, and a contrast enhancement process for enhancing either tissue relative to the other tissue is performed on an image of the object reconstructed using the echo signal on the basis of phase information of the image to acquire a contrast-enhanced image.

Specifically, the MRI apparatus of the invention includes a measurement control unit which controls measurement of an echo signal from an object including a first tissue having a first resonance frequency and a second tissue having a second resonance frequency on the basis of a predetermined pulse sequence, and an arithmetic processing unit which reconstructs an image of the object using the echo signal, wherein the pulse sequence has a RF pre-pulse unit which is provided with an RF pre-pulse having the first resonance frequency for negatively exciting longitudinal magnetization of the first tissue and a measurement sequence unit which measures the echo signal before the longitudinal magnetization excited by the RF pre-pulse is recovered to equal to or greater than zero, and the arithmetic processing unit performs a contrast enhancement process for weighting either tissue relative to the other tissue on an image reconstructed using the echo signal measured by the measurement sequence unit on the basis of phase information of the image to acquire a contrast-enhanced image.

A contrast-enhanced image acquisition method of the invention includes an RF pre-pulse step of applying an RF pre-pulse having the first resonance frequency for negatively exciting longitudinal magnetization of the first tissue to the object, a measurement step of measuring an echo signal from the object before the longitudinal magnetization of the first tissue excited by the RF pre-pulse becomes equal to or greater than zero, an image reconstruction step of reconstructing an image of the object using the echo signal, a phase image calculation step of obtaining a phase image from the reconstructed image, and a contrast enhancement processing step of performing a contrast enhancement process for weighting either tissue relative to the other tissue on the reconstructed image on the basis of the phase image.

### Advantageous Effects of Invention

According to the MRI apparatus and the image contrast enhancement method of the invention, it becomes possible to acquire an image with enhanced contrast between different tissues while reducing an imaging time even if a SPEC-IR pulse is used as an RF pre-pulse.

### BRIEF DESCRIPTION OF DRAWINGS

FIG. 1 is a block diagram showing the overall configuration of an example of an MRI apparatus according to the invention.

FIG. 2(a) is a diagram showing an application timing of an RF pulse (RF) and a generation timing of an echo signal signal in a pulse sequence using a SPEC-IR pulse 201 as an RF pre-pulse, and the behavior of magnetizations of water and fat in conformity with the respective timings of the pulse sequence. FIG. 2(b) shows an absolute value image and a phase image which are obtained by the pulse sequence of FIG. 2(a).

FIG. 3(a) is a diagram showing an application timing of an RF pulse (RF) and a generation timing of an echo signal signal in a pulse sequence using a SPEC-IR pulse 201 as an RF pre-pulse, and the behavior of magnetizations of water and fat in conformity with the respective timings of the pulse sequence. FIG. 3(b) shows an absolute value image and a phase image which are obtained by the pulse sequence of FIG. 3(a).

FIG. 4 is a diagram showing an example of a rephase gradient magnetic field pulse. FIG. 4(a) shows an example of a primary rephase gradient magnetic field waveform, and FIG. 4(b) shows an example of a secondary rephase gradient magnetic field waveform.

FIG. 5 is a sequence chart showing an example of a pulse sequence of the invention. FIG. 5(a) shows an example of a main scan (Main-Scan) sequence. FIG. 5(b) shows an example of a pre-scan sequence.

FIG. 6 is a functional block diagram of each function of an arithmetic processing unit 114 of the invention.

FIG. 7 is a flowchart showing a processing flow of the invention.

FIG. 8 is a diagram showing an execution result of each step of the processing flow shown in FIG. 7 when a two-layered spherical phantom in which water is arranged at the center and a fat layer is arranged around water is used as an object.

### DESCRIPTION OF EMBODIMENTS

Hereinafter, a preferred example of an MRI apparatus of the invention will be described in detail referring to the accompanying drawings. In all the drawings for describing the example of the invention, parts having the same functions are represented by the same reference signs, and description thereof will not be repeated.

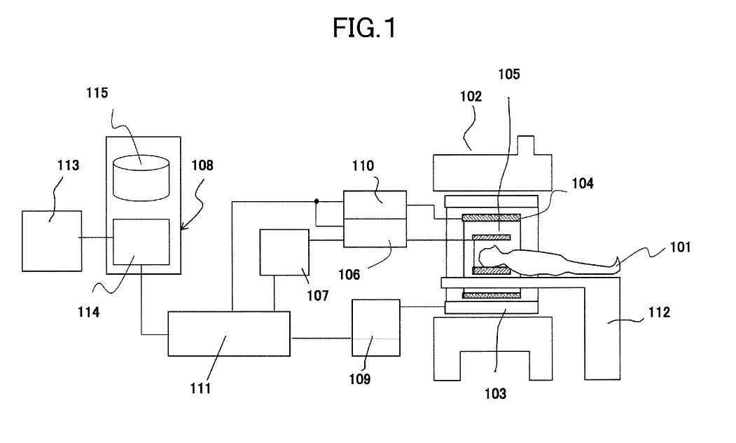

First, an MRI apparatus according to the invention will be described referring to FIG. 1. FIG. 1 is a block diagram showing the overall configuration of an example of an MRI apparatus according to the invention.

The MRI apparatus obtains a tomographic image of an object 101 using an NMR phenomenon, and as shown in FIG. 1, includes a static magnetic field generation magnet 102, a gradient magnetic field coil 103, a gradient magnetic field power supply 109, an RF transmission coil 104, and an RF transmission unit 110, an RF reception coil 105, a signal detection unit 106, a signal processing unit 107, a measurement control unit 111, an overall control unit 108, a display and operating unit 113, and a bed 112 which moves a top plate with an object 101 placed thereon in and out of the static magnetic field generation magnet 102.

The static magnetic field generation magnet 102 generates a uniform static magnetic field in a direction perpendicular to the body axis of the object 101 in the case of a vertical magnetic field system or in a direction of the body axis of the object 101 in the case of a horizontal magnetic field system, and has a permanent magnet-type, normal conducting, or superconducting static magnetic field generation source arranged around the object 101.

The gradient magnetic field coil 103 has coils which are wound in the three-axis direction of X, Y, and Z as a real-space coordinate system (stationary coordinate system) of the MRI apparatus. Each gradient magnetic field coil is connected to the gradient magnetic field power supply 109 which drives the gradient magnetic field coil and is supplied with a current. Specifically, the gradient magnetic field power supply 109 of each gradient magnetic field coil is driven in response to a command from the measurement control unit 111 described below and supplies a current to each gradient magnetic field coil. Accordingly, gradient magnetic fields Gx, Gy, and Gz are generated in the three-axis direction of X, Y, and Z.

During imaging of a two-dimensional slice surface, a slice gradient magnetic file pulse Gs is applied in a direction perpendicular to the slice surface (imaging cross-section), the slice surface with respect to the object 101 is set. Then, a phase-encoded gradient magnetic field pulse Gp and a frequency-encoded (lead-out) gradient magnetic field pulse Gf are applied in the remaining two directions perpendicular to the slice surface and perpendicular to each other, and position information in the respective directions is encoded in an NMR signal (echo signal).

The RF transmission coil 104 is a coil which irradiates an RF pulse onto the object 101. The RF transmission coil 104 is connected to the RF transmission unit 110 and supplied with a high-frequency pulse current. Accordingly, the NMR phenomenon is induced in the spins of the atoms forming a biological tissue of the object 101. Specifically, the RF transmission unit 110 is driven in response to a command from the measurement control unit 111 described below, and a high-frequency pulse is amplitude-modulated, amplified, and supplied to the RF transmission coil 104 near the object 101, whereby the RF pulse is irradiated onto the object 101.

The RF reception coil 105 is a coil which receives an echo signal to be emitted by the NMR phenomenon of the spins forming the biological tissue of the object 101. The RF reception coil 105 is connected to the signal detection unit 106 and sends the received echo signal to the signal detection unit 106.

The signal detection unit 106 performs a detection process of the echo signal received by the RF reception coil 105. Specifically, the signal detection unit 106 amplifies the received echo signal in response to a command from the measurement control unit 111 described below, divides the echo signal into orthogonal signals of two systems by orthogonal phase detection, samples the respective signals in a predetermined number (for example, 128, 256, 512, or the like), A/D converts each sampling signal to a digital quantity, and sends the digital quantity to the signal processing unit 107 described below. Accordingly, the echo signal is obtained as time-series digital data (hereinafter, referred to as echo data) having a predetermined number of pieces of sampling data.

The signal processing unit 107 performs various processes on echo data, and sends the processed echo data to the measurement control unit 111.

The measurement control unit 111 is a control unit which primarily transmits various command to collect echo data required for reconstruction of the tomographic image of the object 101 to the gradient magnetic field power supply 109, the RF transmission unit 110, and the signal detection unit 106 so as to control the gradient magnetic field power supply 109, the RF transmission unit 110, and the signal detection unit 106. Specifically, the measurement control unit 111 operates under the control of the overall control unit 108 described below, controls the gradient magnetic field power supply 109, the RF transmission unit 110, and the signal detection unit 106 on the basis of a predetermined sequence so as to repeatedly execute the irradiation of the RF pulse onto the object 101, the application of the gradient magnetic field pulse, and detection of the echo signal from the object 101, and controls the collection of echo data required for reconstruction of an image for the imaging region of the object 101. The repetition is done while changing the application amount of the phase-encoded gradient magnetic field in the case of two-dimensional imaging and further changing the application amount of the slice-encoded gradient magnetic field in the case of three-dimensional imaging. As the number of phase encodes, a value of 128, 256, 512, or the like per image is usually selected, and as the number of slice encodes, a value of 16, 32, 64, or the like is usually selected. Under this control, echo data from the signal processing unit 107 is output to the overall control unit 108.

The overall control unit 108 performs the control of the measurement control unit 111 and the control of various data processes and the display and storage of the processing results. The overall control unit 108 has an arithmetic processing unit 114 which has an internal CPU and an internal memory, and a storage unit 115, such as an optical disc or a magnetic disk. Specifically, control is performed such that the measurement control unit 111 executes the collection of echo data, and if echo data from the measurement control unit 111 is input, the arithmetic processing unit 114 stores echo data in a region corresponding to a k space in the memory on the basis of encode information applied to echo data. Hereinafter, the description to the effect that echo data is arranged in the k space means that echo data is stored in the region corresponding to the k space in the memory. An echo data group stored in the region corresponding to the k space in the memory is referred to as k space data. The arithmetic processing unit 114 executes a signal process on k space data or a process, such as image reconstruction by Fourier transform, and an image of the object 101 as the processing result is displayed on the display and operating unit 113 described below and recorded in the storage unit 115.

The display and operating unit 113 has a display unit which displays the reconstructed image of the object 101, and an operating unit, such as track ball, a mouse, or a keyboard, which inputs various kinds of information of the MRI apparatus or control information of the processing in the overall control unit 108. The operating unit is arranged near the display unit, and an operator controls various processes of the MRI apparatus interactively through the operating unit while viewing the display unit.

At present, as the nuclear species to be imaged of the MRI apparatus, a hydrogen nucleus (proton) which is a principal constitutive substance of the object is in widespread clinical use. Information relating to the space distribution of proton density or the space distribution of a relaxation time of an excited state is imaged, whereby the shape or function of human head, abdomen, four limbs, or the like is imaged in a two-dimensional or three-dimensional manner.

### (Description of Magnetization and Phase According to the Invention)

Next, the principle of setting a phase difference in the transverse magnetizations of different tissues using an RF pre-pulse as the foundation of the invention will be described. In the following description, in regard to the longitudinal magnetization direction, the longitudinal magnetization direction before being flipped (excited) is referred to as the positive direction and the opposite direction is referred to as the negative direction. In the direction setting, the longitudinal magnetization before being flipped becomes the maximum state toward the positive direction, and becomes the state toward the negative direction after being flipped by greater than 90°. The direction of transverse magnetization which is generated when the longitudinal magnetization is flipped becomes the direction perpendicular to the longitudinal magnetization direction.

According to the invention, an echo signal is measured from an object, which includes a first tissue having a first resonance frequency and a second tissue having a second resonance frequency, using a pulse sequence having an RF pre-pulse unit which is provided with an RF pre-pulse having the first resonance frequency for negatively flipping (exciting) longitudinal magnetization of the first tissue and a measurement sequence unit which measures the echo signal before the longitudinal magnetization excited by the RF pre-pulse is recovered to equal to or greater than zero. In order to negatively excite the longitudinal magnetization, since it should suffice that the longitudinal magnetization is flipped by greater than 90° and equal to or smaller than 180°, the RF pre-pulse excites the longitudinal magnetization of the first tissue to greater than 90° and equal to or smaller than 180°. Preferably, the RF pre-pulse excites only the longitudinal magnetization of the first tissue to greater than 90° and equal to or smaller than 180°. The measurement sequence unit has an RF pulse which excites both the magnetizations of the first tissue and the second tissue.

In the following description of the invention, a case in which
the first tissue is a fat tissue, and the second tissue is a tissue (water tissue) containing plenty of water other than the fat tissue,
a SPEC-IR pulse whose frequency (first resonance frequency) is set so as to flip only the magnetization of the fat tissue (first tissue) is used as the RF pre-pulse, and
a contrast-enhanced image in which a signal of the fat tissue is suppressed and a signal of the water tissue (second tissue) is enhanced relative to the fat tissue is obtained will be described. On the other hand,
the first tissue may be a water tissue and the second tissue may be a fat tissue,
a SPEC-IR pulse whose frequency (first resonance frequency) is set so as to flip only the magnetization of the water tissue (first tissue) may be used as the RF pre-pulse, and
a contrast-enhanced image in which a signal of the water tissue is suppressed and a signal of the fat tissue (second tissue) is enhanced relative to the water tissue may be obtained.

It is known that the resonance frequency (first resonance frequency) of fat is different from the resonance frequency (second resonance frequency) of water by 3.4 ppm, and an RF pulse only having a resonance frequency of one tissue does not flip the longitudinal magnetization of the other tissue. That is, a SPEC-IR pulse only having the resonance frequency of fat flips only the magnetization of the fat tissue.

The invention can be applied to arbitrary tissues having different resonance frequencies, and is not limited to water and fat. That is, the invention acquires a contrast-enhanced image in which either tissue from among arbitrary tissues having different resonance frequencies is enhanced relative to the other tissue. Any RF pulse may be used as an RF pre-pulse insofar as the RF pulse excites longitudinal magnetization of a desired tissue negatively (that is, by greater than 90° and equal to or smaller than 180°).

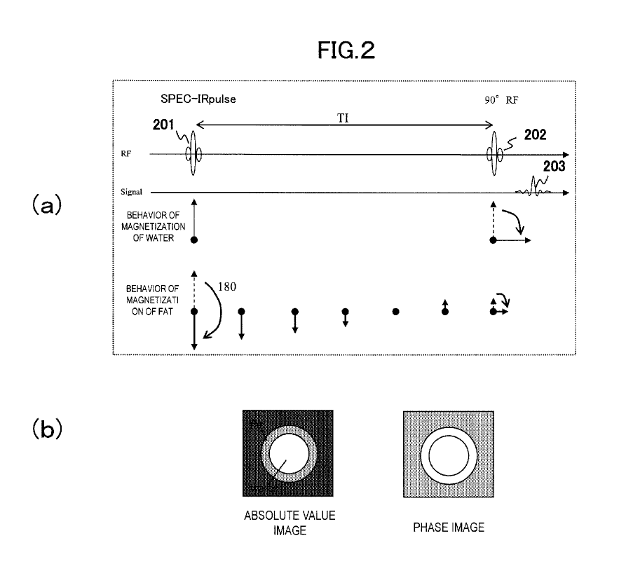

First, for comparison, in a case where the standby time TI from a SPEC-IR pulse in a pre-pulse unit to an RF pulse for measurement of an echo signal for an image (that is, in a measurement sequence unit) is set to be long, and longitudinal magnetization of fat flipped by the SPEC-IR pulse is recovered from a negative state to a positive state by T1, the behavior of magnetization will be described referring to FIG. 2. FIG. 2(a) is a diagram showing an application timing of an RF pulse RF and a generation timing of an echo signal signal in a pulse sequence using a SPEC-IR pulse 201 as an RF pre-pulse, and the behavior of magnetizations of water and fat in conformity with the respective timings of the pulse sequence. FIG. 2(b) shows an absolute value image and a phase image which are obtained by the pulse sequence of FIG. 2(a). The images of FIG. 2(b) are examples when a two-layered spherical phantom in which water is arranged at the center and a fat layer is arranged around water is used as an object.

Since the magnetization of water is not resonant with the frequency of the SPEC-IR pulse 201, the magnetization of water is not flipped even by the application of the SPEC-IR pulse 201, and the longitudinal magnetization maintains the maximum state of the positive (static magnetic field direction) from the application of the SPEC-IR pulse 201 to the application of a 90° RF pulse 202. Meanwhile, since the magnetization of fat is resonant with the frequency of the SPEC-IR pulse 201, the magnetization of fat is flipped by 180° by the application of the SPEC-IR pulse 201 and becomes the maximum longitudinal magnetization state of the negative (opposite static magnetic field direction). Thereafter, the longitudinal magnetization of fat flipped by 180° passes through an exponential recovery process which is defined by the T1 value of fat over time and returns from the maximum negative longitudinal magnetization state to the original maximum positive longitudinal magnetization state. As shown in FIG. 2, if the standby time TI is sufficiently long, the longitudinal magnetization becomes the positive state at the time of the application of the 90° RF pulse 202. That is, although both the longitudinal magnetizations of water and fat become the positive state immediately before the application of the 90° RF pulse 202, the longitudinal magnetization of water becomes the maximum state, and the longitudinal magnetization of fat becomes the positive state smaller than the maximum state.

With the longitudinal magnetization states of water and fat, an echo signal for use in image reconstruction is measured by the measurement sequence unit which starts with the application of the 90° RF pulse 202. Since the longitudinal magnetization of water is placed in the maximum positive state and the longitudinal magnetization of fat is placed in the state smaller than the maximum positive state immediately before the application of the 90° RF pulse 202, the transverse magnetizations of water and fat to be generated by the 90° RF pulse 202 turn toward the same direction, and the phase difference becomes zero. However, since the transverse magnetization of water is large and the transverse magnetization of fat is small, the intensity of an echo signal from water becomes large and the intensity of an echo signal from fat becomes small. Accordingly, when the standby time TI is long such that the longitudinal magnetization of fat which is flipped by the SPEC-IR pulse and becomes the negative state is recovered to the positive state, in a reconstructed image, no difference in phase occurs while a difference in the absolute value occurs between the pixel values of water and fat. For this reason, contrast between the water tissue and the fat tissue has to be added only with the absolute values of the pixel values, and contrast enhancement may be insufficient. In the absolute value image shown in FIG. 2(b), since the longitudinal magnetization of the water tissue is placed in the maximum positive state and the longitudinal magnetization of the fat tissue is placed in the state smaller than the maximum positive state, it is understood that contrast is insufficient while signal intensity differs between the water tissue and the fat tissue. In the phase image, since the phase difference between the water tissue and the fat tissue is zero, it is understood that the phase values are identical.

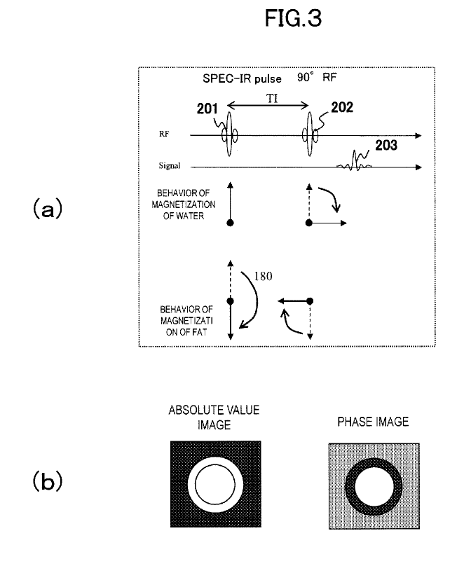

Accordingly, in the invention, the measurement sequence unit which follows after the pre-pulse unit measures the echo signal before the longitudinal magnetization flipped (excited) by the RF pre-pulse of the pre-pulse unit is recovered to equal to or greater than zero. That is, after the application of the RF pre-pulse of the pre-pulse unit, the standby time TI is shortened such that phase difference occurs between the transverse magnetizations of water and fat, and the measurement sequence unit is executed. Accordingly, the measurement sequence unit measures the echo signal in a state where the phase of the transverse magnetization of the first tissue is different from the phase of the transverse magnetization of the second tissue. Then, the absolute value image is weighted using the generated phase difference, and contrast between the water tissue and the fat tissue is enhanced. Here, the short standby time TI means that the time is short such that the longitudinal magnetization of fat which is excited by the SPEC-IR pulse and becomes the negative state maintains the negative state. Preferably, the application of the RF pulse in the measurement sequence unit starts immediately after the application of the SPEC-IR pulse in the pre-pulse unit. In this way, in a case where the standby time TI from the SPEC-IR pulse to the RF pulse for measurement of the echo signal for an image is preferably set to be short, the behavior of the longitudinal magnetization of fat flipped by the SPEC-IR pulse will be described referring to FIG. 3.

FIG. 3(a) is a diagram showing an application timing of an RF pulse RF and a generation timing of an echo signal signal in a pulse sequence using a SPEC-IR pulse 201 as an RF pre-pulse, and the behavior of magnetizations of water and fat at the respective timings of the pulse sequence. FIG. 3(b) shows an absolute value image and a phase image which are obtained by the pulse sequence of FIG. 3(a). Similarly to FIG. 2(b), the images of FIG. 3(b) are examples when a two-layered spherical phantom in which water is arranged at the center and a fat layer is arranged around water is used as an object.

By the application of the SPEC-IR pulse 201, only the longitudinal magnetization of fat is flipped by 180° and becomes the maximum negative longitudinal magnetization state. Thereafter, the sufficiently short standby time TI is left and the 90° RF pulse 202 for measurement of the echo signal for an image (that is, in the measurement sequence unit) is applied. Since the standby time TI is sufficiently short, the longitudinal magnetization of fat is not almost recovered by T1 and maintains the negative state for the standby time TI. In this state, if the 90° RF pulse 202 for measurement of the echo signal for an image is applied, the longitudinal magnetization of water is placed in the maximum positive state immediately before the 90° RF pulse 202 while the longitudinal magnetizations of water and fat are respectively flipped by 90°. For this reason, the longitudinal magnetization of water is changed to the positive transverse magnetization (in this case, the transverse magnetization direction of water is the positive direction) by the 90° RF pulse 202.

On the other hand, since the longitudinal magnetization of fat is placed in the negative state immediately before the 90° RF pulse 202, the longitudinal magnetization of fat is changed to the negative transverse magnetization (that is, the transverse magnetization turns toward an opposite direction with respect to the transverse magnetization of water) by the 90° RF pulse 202. As a result, the phases of the transverse magnetizations of water and fat are different by π (180°) (or the polarities of the phases are different), and in a complex image reconstructed from the measured echo signal for an image, the phase of the pixel value of the water tissue and the phase of the pixel value of the fat tissue are different by π (or the polarities of the phases are different). In the absolute value image shown in FIG. 3(b), since the longitudinal magnetization of the water tissue is placed in the maximum positive state and the longitudinal magnetization of the fat tissue is substantially placed in the maximum negative state, it is understood that the absolute values are substantially identical and signal intensity is maximal. In the phase image, it is understood that the phase difference between the water tissue and the fat tissue becomes π.

Accordingly, according to the invention, a contrast enhancement process for enhancing either tissue relative to the other tissue is performed on an image of the object reconstructed using the echo signal measured in the above-described manner on the basis of phase information of the image to acquire a contrast-enhanced image. Specifically, an absolute value image having the absolute value of the complex image is weighted using the phase difference between the water tissue and the fat tissue in the thus-obtained complex image. Accordingly, it is possible to further enhance contrast between the water tissue and the fat tissue compared to a case where contrast enhancement is made only by the absolute values of the pixel values. That is, it becomes possible to obtain an image with more enhanced contrast between the water tissue and the fat tissue while reducing the standby time (preferably, shortest) compared to a case where the standby time TI is extended. In the example shown in FIG. 3(b), each pixel value of the absolute value image is weighted on the basis of the phase image in which the phase difference between the water tissue and the fat tissue is π, and contrast between the water tissue and the fat tissue in the absolute value image is enhanced. Accordingly, an image in which contrast is further enhanced compared to contrast between the water tissue and the fat tissue in the absolute value image shown in FIG. 2(b) is obtained.

### (For Removal of Phase Errors Due to Other Factors)

In general, since phase errors which are generated by imaging other than the π phase difference (opposite phase polarity) given by the RF pre-pulse are mixed in the complex image, it is necessary to remove the phase errors.

The phase errors include a phase error which is accumulated during the measure of the echo signal for an image due to resonance frequency shift, such as static magnetic field ununiformity or chemical shift, a phase error due to incompleteness of hardware, such as delay of a gradient magnetic field application timing with respect to A/D, and a phase error due to the motion of the object.

In regard to the phase error which is temporally accumulated due to the resonance frequency shift, it is generally known that the phase error is cancelled in a spin echo-based sequence which uses a 180° re-converging RF pulse between the excitation by the 90° RF pulse and the echo time TE. For this reason, the phase error which is temporally accumulated is negligible. Meanwhile, in a gradient echo-based sequence, since there is no 180° re-converging RF pulse, the phase error which is temporally accumulated is not negligible. For this reason, a phase image (reference phase image) when the RF pre-pulse is not applied is imaged by preliminary measurement (Pre-Scan) in advance, and a differential process between the phase image when the RF pre-pulse is used and the reference phase image is performed, thereby removing the phase error which is temporally accumulated. The reference phase image which is obtained by pre-scan includes the phase error due to incompleteness of hardware. That is, the reference phase image includes the phase error which is temporally accumulated due to the resonance frequency shift and the phase error due to incompleteness of hardware. Since the two kinds of phase errors undergo a gradual spatial phase change, the reference phase image represents the two kinds of phase errors with sufficient precision even if spatial resolution is low. For this reason, pre-scan for acquiring the reference phase image is sufficiently made by low spatial resolution (for example, about 32*32 matrix) imaging with a short measurement time.

With the use of a multi-echo sequence which successively acquires two or more echo signals with different echo times TE, a frequency shift may be calculated from the time difference and phase difference between the echo signals, and a phase error at the intended echo time TE can be calculated from the frequency shift and removed.

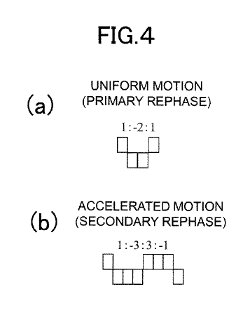

In regard to the phase error due to the motion of the object, such as a blood flow, or the motion (uniform motion or accelerated motion) inside the object, a primary rephase gradient magnetic field pulse based on a known GMN (Gradient Moment Nulling) method or a higher-order rephase gradient magnetic field pulse is applied to the pulse sequence, thereby removing the effect of the motion. FIG. 4 shows an example of a rephase gradient magnetic field pulse. In order to suppress a phase error due to uniform motion (primary), with a configuration of three gradient magnetic field pulses shown in FIG. 4(a), a gradient magnetic field pulse waveform in which intensity (absolute value) is constant and the area ratio becomes 1:−2:1 is applied in the uniform motion direction. In order to suppress a phase error due to the accelerated motion (secondary), with a configuration of four gradient magnetic field pulses shown in FIG. 4(b), a gradient magnetic field pulse waveform in which intensity is constant and the area ratio becomes 1:−3:3:−1 is applied in the accelerated motion direction.

As described above, phase measured by pre-scan, multi-echo measurement, and the primary rephase gradient magnetic field pulse or higher-order rephase gradient magnetic field pulse are combined, thereby removing various phase errors. For this reason, it is possible to extract only the phase difference based on the difference in the resonance frequency between tissues having different resonance frequencies due to the RF pre-pulse. It becomes possible to enhance image contrast using the phase difference.

### (Pulse Sequence of the Invention)

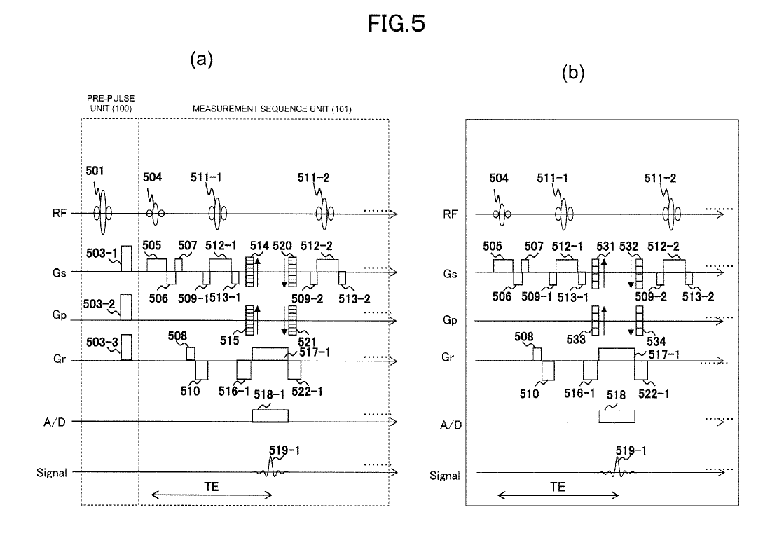

Next, the pulse sequence of the invention will be described referring to FIG. 5. FIG. 5 is a sequence chart showing an example of the pulse sequence of the invention. FIG. 5(a) shows an example of a main scan (Main-Scan) sequence in which a pre-pulse unit 100 which applies a SPEC-IR pulse as an RF pre-pulse is provided before the measurement sequence unit 101 which uses a fast-spin echo (Fast-Spin Echo) sequence for measurement of the echo signal for an image. FIG. 5(b) shows an example of a pre-scan sequence corresponding to imaging with low spatial resolution when the pre-pulse unit 100 is excluded from FIG. 5(a), and the amount of change in the slice/phase encoded gradient magnetic field pulse in the measurement sequence unit 101 increases. The pulse sequence for use in the measurement sequence unit of the invention is not limited to the fast-spin echo sequence, and other pulse sequences may be used. The RF pre-pulse of the invention is not limited to the SPEC-IR pulse, and all RF pulses may be used insofar as desired magnetization can be flipped to greater than 90° and equal to or smaller than 180° by the RF pre-pulse.

First, an example of a main scan sequence having the pre-pulse unit 100 and the measurement sequence unit 101 will be described referring to FIG. 5(a).

The pre-pulse unit 100 has a SPEC-IR pulse 501 and spoiler gradient magnetic field pulses 503-1 to 503-3. The SPEC-IR pulse 501 is an example of the RF pre-pulse, and only the longitudinal magnetization of the fat tissue having the resonance frequency (first resonance frequency) of fat is selectively inversed by 180° using a difference in chemical shift. After the SPEC-IR pulse 501, spoiler gradient magnetic field pulses 503-1 to 503-3 are applied in at least one axis direction of a slice direction Gs, a phase encode direction Gp, and a read direction Gr, preferably, in the three-axis direction, transverse magnetization which occurs due to excitation to less than 180° by the SPEC-IR pulse 501 is eliminated.

The measurement sequence unit 101 measures the echo signal on the basis of the fast-spin echo sequence. After the slice selection gradient magnetic field pulse 505 is applied simultaneously with a 90° pulse (504) which flips both the longitudinal magnetizations of the water tissue and the fat tissue by 90°, in order to correct the effect of the motion, primary rephase gradient magnetic field pulses 506 and 507 in which the ratio of gradient magnetic field intensity is 1:−1:1, the ratio of the application time is 1:2:1, and the ratio of the area is 1:−2:1 are applied in the slice direction. Next, a slice selection gradient magnetic field pulse 512-1 is applied simultaneously with a 180° refocus pulse 511-1, and rephase gradient magnetic field pulses 509-1 and 513-1 in the slice direction in which the application time is ⅙ of the slice selection gradient magnetic field pulse 512-1 are applied before and after application of the slice selection gradient magnetic field pulse 512-1. In the secondary rephase, since the gradient magnetic field polarity to be sensed by the transverse magnetization is inversed before and after the center of the 180° refocus pulse 511-1, a rephase gradient magnetic field pulse in which the ratio of the application area of the gradient magnetic field pulse becomes 1:−3:3:−1 is applied. Secondary rephase gradient magnetic field pulses 508, 510, and 516-1 and a read gradient magnetic field pulse 517-1 are applied in the read direction Gr. At the center of the read gradient magnetic field pulse 517-1, in order to detect a peak of the echo signal, if the gradient magnetic field pulses to the center of 508, 510, 516-1, and 517-1 are unitized as one gradient magnetic field pulse, the application time is identical, and the gradient magnetic field intensity ratio is 1:−3:−3:1. In this way, since the magnetic field to be sensed by the transverse magnetization is inverted before and after the center of the 180° refocus pulse 511-1, a secondary rephase gradient magnetic field pulse in which the area ratio becomes 1:−3:3:−1 can be made.

At the timing of the rephase gradient magnetic field pulse 516-1 in the read direction Gr, a slice-encoded gradient magnetic field pulse 514 is applied in the slice direction Gs and a phase-encoded gradient magnetic field pulse 515 is applied in the phase encode direction (Gp). After the read gradient magnetic field pulse 517 is applied, rewind gradient magnetic field pulses 520 and 521 are applied in the slice direction Gs and the phase encode direction Gp. The gradient magnetic field pulses 514, 515, 520, and 521 are controlled so as to change for each 180° refocus pulse, whereby various encodes are carried out.

At the time of the application of the read gradient magnetic field pulse 517-1, A/D 518-1 is performed to measure an echo signal 519-1. In the read direction Gr, if a rephase gradient magnetic field pulse 522-1 of the same form as 516-1 is applied after the application of the read gradient magnetic field pulse, and the gradient magnetic fields of the right half of 517-1 and 522-1 before the next 180° refocus pulse 511-2 and the left halves of 516-2 and 517-2 to be subsequently repeated are unitized as one gradient magnetic field pulse, since the gradient magnetic field area ratio of 1:−3:3:−1 is established, the secondary rephase is repeated.

Next, the pre-scan sequence only having the measurement sequence unit 101 will be described referring to FIG. 5(b). FIG. 5(b) is an example of a pre-scan sequence corresponding to imaging with low spatial resolution when the pre-pulse unit 100 is excluded from FIG. 5(a), and the amount of change in the slice/phase-encoded gradient magnetic field pulses 531, 532, 533, and 534 in the measurement sequence unit 101 increases. Other parts are the same as those in the main scan sequence of FIG. 5(a), thus detailed description will not be repeated. A phase image is acquired using the echo signal measured by the pre-scan sequence, thus, as described above, it becomes possible to collectively acquire various phase errors, other than the phase difference based on the difference in the resonance frequency between the tissues, which are caused by the SPEC-IR pulse 501 as the RF pre-pulse.

### (Description of Functional Processing Unit of the Invention)

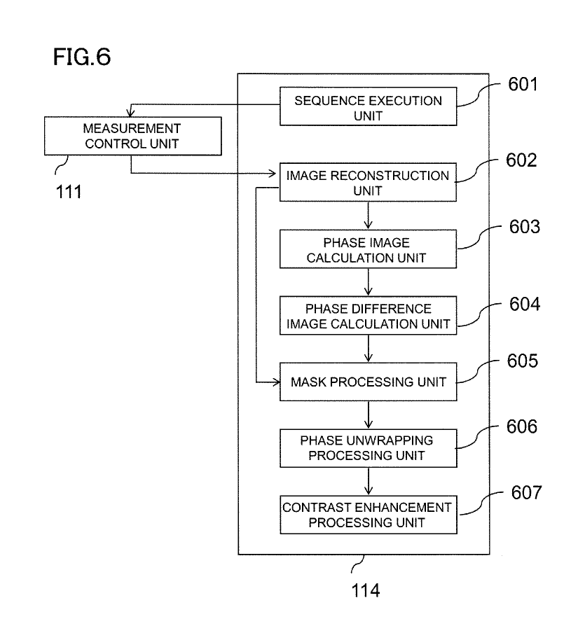

Next, each arithmetic processing function of the arithmetic processing unit 114 of the invention will be described referring to FIG. 6. FIG. 6 is a functional block diagram of each function of the arithmetic processing unit 114 of the invention. Each arithmetic processing function according to the invention has a sequence execution unit 601, an image reconstruction unit 602, a phase image calculation unit 603, a phase difference image calculation unit 604, a mask processing unit 605, a phase unwrapping processing unit 606, and a contrast enhancement processing unit 607.

The sequence execution unit 601 causes the measurement control unit 111 to execute the pre-scan sequence and the main scan sequence.

The image reconstruction unit 602 performs Fourier transform on data (echo data) of the echo signals measured by the pre-scan sequence and the main scan sequence, and reconstructs a complex image. The absolute value of each pixel of the complex images is calculated to obtain an absolute value image.

The phase image calculation unit 603 calculates a complex number of phase as the pixel value for each pixel of the complex image, and obtains a phase image.

The phase difference image calculation unit 604 calculates the difference between the pixels of two phase images, and obtains a phase difference image.

The mask processing unit 605 compares the pixel value for each pixel of an input image with a predetermined threshold value, and converts the pixel value to a value in a predetermined range (for example, a value of 0 to 1) to create a mask image. The created mask image is given to the other image, that is, a mask process for multiplication for each pixel is performed, and an image after the mask process is obtained.

The phase unwrapping processing unit 606 performs a phase unwrapping process for removing the surrounding of the principal value in each pixel value of the input phase image, and obtains a phase image after the unwrapping process.

The contrast enhancement processing unit 607 performs a contrast enhancement process by weighting the absolute value image on the basis of the phase difference image (phase information). Specifically, the weighting factor of each pixel is decided on the basis of the pixel value (phase difference) of each pixel of the phase difference image, and the decided weighting factor is multiplied to the pixel value of the pixel corresponding to the absolute value image to weight the pixel value. The weighting process based on the phase difference image is the contrast enhancement process, and an image after the contrast enhancement process becomes a contrast-enhanced image.

Hereinafter, a specific process of each functional unit will be described through specific description of the processing flow of the invention which is performed by the respective units in cooperation.

### (Processing Flow of the Invention)

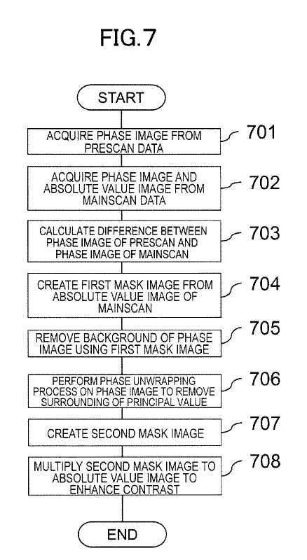

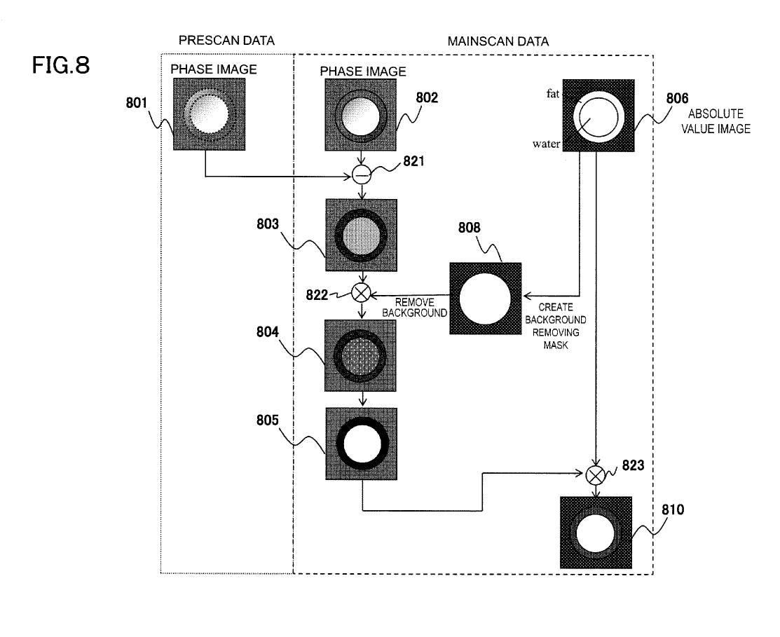

Next, the processing flow of the invention will be described referring to FIG. 7. FIG. 7 is a flowchart showing the processing flow of the invention. This processing flow is stored in the storage unit as a program in advance, and is carried out when the arithmetic processing unit 114 reads the program from the storage unit and executes the program. FIG. 8 shows an example of an execution result of each step of the processing flow shown in FIG. 7 when a two-layered spherical phantom in which water is arranged at the center and a fat layer is arranged around water is used as an object. Hereinafter, the details of a process of each step will be described.

In Step 701, the sequence execution unit 601 causes the measurement control unit 111 to execute the pre-scan sequence shown in FIG. 5(b). The measurement control unit 111 receives the instruction, executes the pre-scan sequence shown in FIG. 5(b) to control the measurement of the echo signal, and notifies the arithmetic processing unit 114 of data (echo data) of the measured echo signal. The image reconstruction unit 602 performs Fourier transform on echo data to obtain a complex image with low spatial resolution. The phase image calculation unit 603 obtains a phase image (first phase image) 801 with low spatial resolution from the obtained complex image. As described above, the first phase image collectively includes various phase errors other than the phase difference which are caused by the SPEC-IR pulse 501.

In Step 702, the sequence execution unit 601 causes the measurement control unit 111 to execute the main scan sequence shown in FIG. 5(a). the measurement control unit 111 receives the instruction, executes the main scan sequence shown in FIG. 5(a) to control the measurement of the echo signal, and notifies the arithmetic processing unit 114 of data (echo data) of the measured echo signal. The image reconstruction unit 602 performs Fourier transform on echo data to obtain a complex image and an absolute value image 806. The phase image calculation unit 603 obtains phase image (second phase image) 802 from the obtained complex image.

In Step 703, after the first phase image obtained in Step 701 is converted to the phase image with the same spatial resolution as the second phase image, the phase difference image calculation unit 604 performs differential process (821) from the second phase image obtained in Step 702, and obtains a phase difference image 803. In the phase difference image 803, the phase error due to the resonance frequency shift and the phase error due to incompleteness of hardware are removed, and the phase difference image 803 becomes a phase image in which only the phase difference caused by the SPEC-IR pulse 501 is reflected.

In Step 704, the mask processing unit 605 sets a threshold value (for example, 20% of the maximum value in the absolute value of each pixel value) with respect to the pixel value (absolute value) of each pixel of the absolute value image 806 obtained in Step 702, and excludes pixels having a pixel value smaller than the threshold value as background, thereby creating a first mask image 808 for extracting only an object region in the absolute value image 806. Specifically, 0 is allocated to a pixel having a pixel value smaller than the threshold value, and 1 is allocated to a pixel having a pixel value greater than the threshold value, thereby creating the first mask image 808.

In Step 705, the mask processing unit 605 gives the first mask image 808 created in Step 704 to the phase difference image 803 obtained in Step 703, that is, performs the mask process (822) for multiplying the first mask image 808 to the phase difference image 803 for each pixel, and obtains a phase difference image 804 in which the background region is excluded from the phase difference image 803 and only the object region is extracted. A predetermined value (for example, 0) is allocated to the pixel value (phase value) of the excluded background region. The value of the background region of the first mask image 808 is 0, and if multiplied for each pixel, the value inevitably becomes 0.

In Step 706, the phase unwrapping processing unit 606 performs the phase unwrapping process on the phase difference image 804 subjected to the mask process in Step 705 to remove the surrounding of the principal value. The phase value of water is a reference phase θ_{ref}, and the differences (θ−θ_{ref}) between the phase values θ of all pixels and the reference phase θ_{ref} are obtained, that is, the reference phase is subtracted uniformly from the pixel values of the phase difference image to create a corrected phase difference image. The corrected phase difference image is an image which represents a differential phase from the phase value of water, the phase of the water tissue becomes zero, and the phase of the fat tissue becomes π.

In Step 707, the contrast enhancement processing unit 607 decides the weighting factor of each pixel on the basis of the pixel value (phase difference) of each pixel of the corrected phase difference image obtained in Step 706, and creates a second mask image 805 which represents the distribution of the decided weighting factor. Specifically, a predetermined threshold value (for example, ±π/2) is set with respect to the pixel value of each pixel of the corrected phase difference image obtained in Step 706, and when the absolute value of the phase value θ as the pixel value is smaller than the threshold value (that is, −π/2<θ<+π/2), the phase value is converted to 1, otherwise (that is, [θ<=−π/2] or [+π/2<=θ]), the phase value is converted to the value of [0 to 1], and the converted value is set as the weighting factor of each pixel. For example, when suppressing a signal largely, a value near 0 is set. With this conversion, the phase of the fat tissue (first tissue) is converted to the weighting factor of [0 to 1], and the phase of the water tissue (second tissue) is converted to the weighting factor of [1]. Similarly, the weighting factor is decided for all pixels of the corrected phase difference image, and the second mask image 805 which represents the weighting factor distribution of the respective pixels is created. The second mask image 805 becomes a contrast enhancing mask image.

In Step 708, the contrast enhancement processing unit 607 gives the second mask image 805 obtained in Step 707 to the absolute value image 806 obtained in Step 702 (823). Specifically, the weighting process for weighting the pixel value of each pixel of the absolute value image 806 with the pixel value of the second mask image 805 is performed by multiplying the pixel values of the absolute value image 806 and the second mask image 805 for the same pixels (823). The weighting process 823 using the second mask image 805, that is, based on the phase difference image 803 is the contrast enhancement process, and a contrast-enhanced image 810 is obtained by the contrast enhancement process. The contrast-enhanced image 810 becomes an image in which a fat region in the absolute value image 806 is suppressed. That is, the contrast-enhanced image 810 becomes an image in which contrast between the water tissue and the fat tissue in the absolute value image 806 is enhanced. In the example of the contrast-enhanced image 810 shown in FIG. 8, it is understood that an image in which a signal of the fat tissue is suppressed and only luminance of the water tissue is enhanced is obtained.

The above description relates to the processing flow of the contrast-enhanced image acquisition method of the invention.

Although the example of the invention has been described, the invention is not limited thereto.

Although in the above description, an example where the phase error is extracted by the pre-scan has been described, in a highly adjusted MRI apparatus, since phase errors are less, the pre-scan may not be required. For this reason, even if the pre-scan is not provided, and only the main scan is carried out, the invention is established. That is, in a highly adjusted MRI apparatus, the second mask image 805 may be obtained on the basis of the phase image 804 which is obtained by directly giving the first mask image 808 to the phase image 802.

Although in Step 707, the weighting factor has been decided such that the signal of the fat tissue is suppressed relative to the signal of the water tissue, conversely, the weighting factor may be decided such that the signal of the water tissue is suppressed relative to the signal of the fat tissue. Specifically, when the absolute value of the pixel value (phase value) θ of each pixel of the corrected phase difference image is smaller than the threshold value (that is, −π/2<θ<+π/2), the pixel value may be converted to [0 to 1], otherwise (that is, [θ<=−π/2] or [+π/2<=θ]), the pixel value may be converted to 1, and the converted value may be set as the weighting factor of each pixel.

As described above, according to the invention, an echo signal is measured from an object, which includes a first tissue having a first resonance frequency and a second tissue having a second resonance frequency, using a pulse sequence having a RF pre-pulse unit which is provided with an RF pre-pulse having the first resonance frequency for negatively exciting longitudinal magnetization of the first tissue and a measurement sequence unit which measures the echo signal before the longitudinal magnetization excited by the RF pre-pulse is recovered to equal to or greater than zero, and a contrast enhancement process for enhancing either tissue relative to the other tissue is performed on an image of the object reconstructed using the echo signal on the basis of phase information of the image to acquire a contrast-enhanced image. Specifically, the MRI apparatus of the invention includes the contrast enhancement processing unit which performs the contrast enhancement process for enhancing either tissue relative to the other tissue on the image reconstructed using the echo signal measured by the measurement sequence unit on the basis of phase information of the image to acquire the contrast-enhanced image. The contrast-enhanced image acquisition method of the invention has a contrast enhancement processing step of obtaining the phase image from the reconstructed image of the object and performing the contrast enhancement process for enhancing either tissue relative to the other tissue on the reconstructed image on the basis of the phase image.

With the above configuration, according to the MRI apparatus and the contrast-enhanced image acquisition method of the invention, the phase difference it is set between the first tissue and the second tissue to obtain the phase difference image, and the absolute value image is weighted on the basis of the phase difference image, whereby it is possible to acquire a contrast-enhanced image with more enhanced contrast between the first tissue and the second tissue compared to a method in which the standby time TI is extended and contrast is added only with a difference in signal intensity contrast. Since it is possible to set the short standby time TI from the application of the RF pre-pulse to the execution of the measurement sequence unit, thereby reducing an imaging time.

### REFERENCE SIGNS LIST

101: object, 102: static magnetic field generation magnet, 103: gradient magnetic field coil, 104: transmission RF coil, 105: RF reception coil, 106: signal detection unit 106, 107: signal processing unit, 108: overall control unit, 109: gradient magnetic field power supply, 110: RF transmission unit, 111: measurement control unit, 112: bed, 113: display and operating unit, 114: arithmetic processing unit, 115: storage unit

1. A magnetic resonance imaging apparatus comprising:
a measurement control unit which controls measurement of an echo signal from an object including a first tissue having a first resonance frequency and a second tissue having a second resonance frequency on the basis of a predetermined pulse sequence; and
an arithmetic processing unit which reconstructs an image of the object using the echo signal;
wherein the pulse sequence has a RF pre-pulse unit which is provided with an RF pre-pulse having the first resonance frequency for negatively exciting longitudinal magnetization of the first tissue and a measurement sequence unit which measures the echo signal before the longitudinal magnetization excited by the RF pre-pulse is recovered to equal to or greater than zero, and
the arithmetic processing unit performs a contrast enhancement process for weighting either tissue relative to the other tissue on an image reconstructed using the echo signal measured by the measurement sequence unit on the basis of phase information of the image to acquire a contrast-enhanced image.

2. The magnetic resonance imaging apparatus according to claim 1,
wherein the RF pre-pulse excites only the longitudinal magnetization of the first tissue to be greater than 90° and equal to or smaller than 180°.

3. The magnetic resonance imaging apparatus according to claim 1,
wherein the measurement sequence unit has a 90° RF pulse and excites both the longitudinal magnetizations of the first tissue and the second tissue to 90°.

4. The magnetic resonance imaging apparatus according to claim 1,
wherein the measurement sequence unit includes a rephase gradient magnetic field pulse based on a GMN method in at least one direction of a slice direction and a read direction.

5. The magnetic resonance imaging apparatus according to claim 3,
wherein the measurement sequence unit performs the measurement of the echo signal in a state where the phase of transverse magnetization of the first tissue and the phase of transverse magnetization of the second tissue are different.

6. The magnetic resonance imaging apparatus according to claim 1,
wherein the RF pre-pulse unit applies a spoiler gradient magnetic field pulse in at least one axial direction after the RF pre-pulse.

7. The magnetic resonance imaging apparatus according to claim 1,
wherein the arithmetic processing unit determines a weighting factor of each pixel for the contrast enhancement process on the basis of a phase image of the image reconstructed using the echo signal measured by the measurement sequence unit.

8. The magnetic resonance imaging apparatus according to claim 7,
wherein the arithmetic processing unit determines a weighting factor of each pixel on the basis of a phase difference image between a phase image of the image reconstructed using the echo signal measured by the measurement sequence unit with no RF pre-pulse unit and a phase image of the image reconstructed using the echo signal measured by the measurement sequence unit with the RF pre-pulse unit, creates a contrast enhancing mask image which represents the distribution of the weighting factor and is used for the contrast enhancement process, and multiplies the contrast enhancing mask image to an absolute value image of the reconstructed image for each pixel to acquire the contrast-enhanced image.

9. The magnetic resonance imaging apparatus according to claim 7,
wherein the arithmetic processing unit respectively converts the phases of the first tissue and the second tissue in the phase difference image to values [0 to 1] and [1] to determine the weighting factor.

10. The magnetic resonance imaging apparatus according to claim 8,
wherein the arithmetic processing unit creates a mask which extracts a region where each pixel value of the absolute value image of the reconstructed image is greater than a predetermined threshold value, and multiplies the mask to the phase difference image to remove a phase difference of a background noise region in the phase difference image.

11. The magnetic resonance imaging apparatus according to claim 8,
wherein the arithmetic processing unit performs a phase unwrapping process on each pixel value of the phase difference image.

12. A contrast-enhanced image acquisition method which acquires an image of an object including a first tissue having a first resonance frequency and a second tissue having a second resonance frequency while enhancing either tissue relative to the other tissue, the contrast-enhanced image acquisition method comprising:
an RF pre-pulse step of applying an RF pre-pulse having the first resonance frequency for negatively exciting longitudinal magnetization of the first tissue to the object;
a measurement step of measuring an echo signal from the object before the longitudinal magnetization of the first tissue excited by the RF pre-pulse becomes equal to or greater than zero;
an image reconstruction step of reconstructing an image of the object using the echo signal;
a phase image calculation step of obtaining a phase image from the reconstructed image; and
a contrast enhancement processing step of performing a contrast enhancement process for weighting either tissue relative to the other tissue on the reconstructed image on the basis of the phase image.

13. The contrast-enhanced image acquisition method according to claim 12,
wherein, in the contrast enhancement processing step, the contrast enhancement process is performed on the basis of a phase image of the reconstructed image.

14. The contrast-enhanced image acquisition method according to claim 13,
wherein, in the contrast enhancement processing step, a contrast enhancing mask for enhancing either tissue relative to the other tissue is created on the basis of a phase difference image between a phase image acquired by pre-scan using only the measurement sequence unit with no RF pre-pulse and the phase image of the reconstructed image, and the contrast enhancing mask is multiplied to an absolute value image of the reconstructed image to acquire the contrast-enhanced image.

15. The contrast-enhanced image acquisition method according to claim 14,
wherein, in the contrast enhancement processing step, the phases of the first tissue and the second tissue in the phase difference image are respectively converted to values of [0 to 1] and [1] to create the contrast enhancing mask.
